(19) United States
(12) Patent Application Publication
(10) Pub. No.: US 2014/0177347 A1
(43) Pub. Date: Jun. 26, 2014

(54) INTER-ROW DATA TRANSFER IN MEMORY DEVICES

(71) Applicant: ADVANCED MICRO DEVICES, INC., Sunnyvale, CA (US)

(72) Inventors: Niladrish Chatterjee, Salt Lake City, UT (US); James O'Connor, Austin, TX (US); Nuwan Jayasena, Sunnyvale, CA (US); Gabriel Loh, Bellevue, WA (US)

(73) Assignee: ADVANCED MICRO DEVICES, INC., Sunnyvale, CA (US)

(21) Appl. No.: 13/721,315

(22) Filed: Dec. 20, 2012

(51) Int. Cl. G11C 7/00

(52) U.S. Cl. CPC G11C 7/00
USPC 365/189.05

(57) ABSTRACT

A method and apparatus for inter-row data transfer in memory devices is described. Data transfer from one physical location in a memory device to another is achieved without engaging the external input/output pins on the memory device. In an example method, a memory device is responsive to a row transfer (RT) command which includes a source row identifier and a target row identifier. The memory device activates a source row and storing source row data in a row buffer, latches the target row identifier into the memory device, activates a word line of a target row to prepare for a write operation, and stores the source row data from the row buffer into the target row.

### TECHNICAL FIELD

The disclosed embodiments are generally directed to memory devices, and in particular, to memory device processing.

### BACKGROUND

Modern memory devices, such as those based on dynamic random access memory (DRAM) and phase change memory (PCM) technology, consist of several independent banks, each of which is arranged as a two-dimensional array of memory cells. To access a row or block of data, a memory controller issues an activation command followed by multiple read or write commands over a memory channel to the memory device. In many situations, it might be useful to move data from one row of a bank to another row in the bank. These intra-bank, inter-row data transfers can be achieved in conventional systems by having the memory controller issue a series of multiple read commands followed by a series of multiple write commands over the memory channel.

In these conventional systems, the memory channel remains occupied for the entire duration of the intra-bank, inter-row data transfer. This bandwidth use can be viewed as a waste of bandwidth because the compute units do not benefit directly from this data transfer. There is a significant command and address bus bandwidth waste doing these transfers. Since memory bandwidth is one of the most important system resources, this can result in significant lost performance potential. In addition, the bank involved in the data transfer cannot service any other requests to the bank when occupied by the data transfer. This reduction in available bandwidth and the consequent contention for the banks arises even if other requests can be interleaved among the read or write requests. The data transfers across the interface to and from the DRAM also require potentially significant energy, particularly in high-frequency memory systems.

### SUMMARY OF EMBODIMENTS

A method and apparatus for inter-row data transfer in memory devices is described. Data transfer from one physical location in a memory device to another is achieved without engaging the external input/output pins on the memory device. In some embodiments, a memory device is responsive to a row transfer (RT) command which includes a source row identifier and a target row identifier. The memory device activates a source row and stores source row data in a row buffer, latches the target row identifier into the memory device, activates a word line of a target row to prepare for a write operation, and stores the source row data from the row buffer into the target row.

### BRIEF DESCRIPTION OF THE DRAWINGS

A more detailed understanding may be had from the following description, given by way of example in conjunction with the accompanying drawings wherein:

FIG. 1 is a block diagram of an example device in which some embodiments may be implemented;

FIG. 2 is a block diagram of another example device in which some embodiments may be implemented;

FIG. 3 is a block diagram of an example memory device architecture in accordance with some embodiments;

FIG. 4 is an example operation flowchart for a row transfer (RT) command in accordance with some embodiments;

FIG. 5 is another example operation flowchart for a RT command in accordance with some embodiments; and

FIG. 6 is an example operation flowchart for a precharge to addressed row (PREAR) command in accordance with some embodiments.

### DETAILED DESCRIPTION

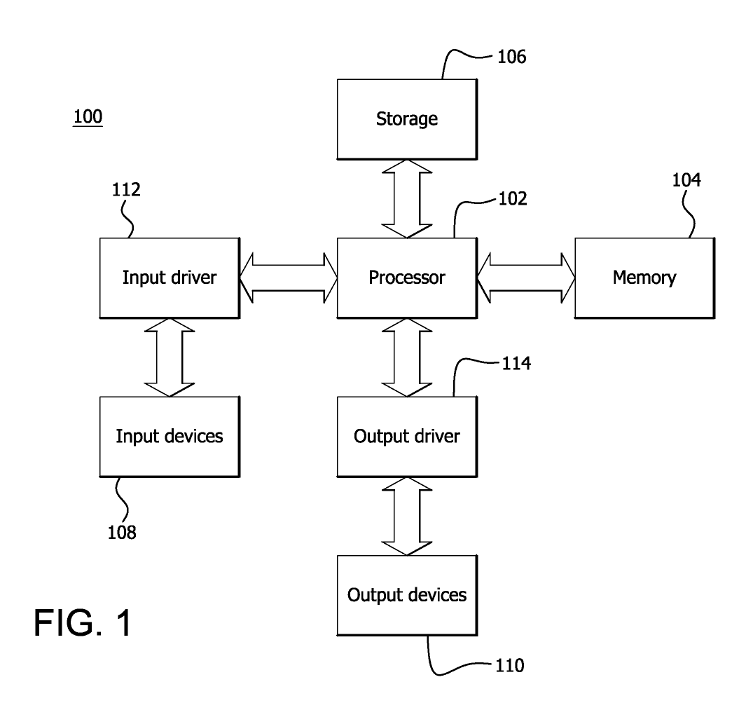

FIG. 1 is a block diagram of an example device 100 in which some embodiments may be implemented. The device 100 may include, for example, a computer, a gaming device, a handheld device, a set-top box, a television, a mobile phone, or a tablet computer. The device 100 includes a processor 102, a memory 104, a storage 106, one or more input devices 108, and one or more output devices 110. The device 100 may also optionally include an input driver 112 and an output driver 114. It is understood that the device 100 may include additional components not shown in FIG. 1.

The processor 102 may include a central processing unit (CPU), a graphics processing unit (GPU), a CPU and GPU located on the same die, or one or more processor cores, wherein each processor core may be a CPU or a GPU. The memory 104 may be located on the same die as the processor 102, or may be located separately from the processor 102. The memory 104 may include a volatile or non-volatile memory, for example, random access memory (RAM), dynamic RAM, or a cache.

The storage 106 may include a fixed or removable storage, for example, a hard disk drive, a solid state drive, an optical disk, or a flash drive. The input devices 108 may include a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals). The output devices 110 may include a display, a speaker, a printer, a haptic feedback device, one or more lights, an antenna, or a network connection (e.g., a wireless local area network card for transmission and/or reception of wireless IEEE 802 signals).

The input driver 112 communicates with the processor 102 and the input devices 108, and permits the processor 102 to receive input from the input devices 108. The output driver 114 communicates with the processor 102 and the output devices 110, and permits the processor 102 to send output to the output devices 110. It is noted that the input driver 112 and the output driver 114 are optional components, and that the device 100 will operate in the same manner if the input driver 112 and the output driver 114 are not present.

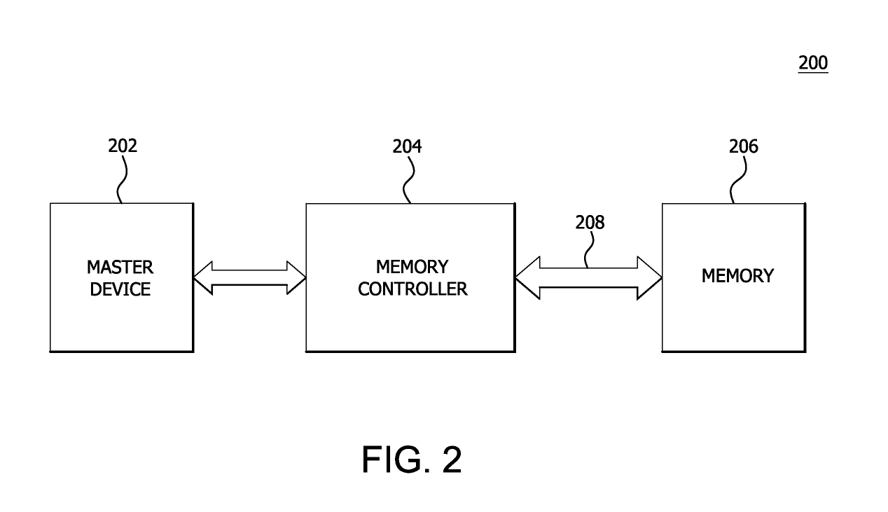

FIG. 2 is a block diagram of an example device 200 in which some embodiments may be implemented. The device 200 may include, for example, a computer, a gaming device, a handheld device, a set-top box, a television, a mobile phone, or a tablet computer. The device 200 includes a master device 202, a memory controller 204 and a memory device 206. The memory controller 204 issues commands to the memory device 206 over a memory channel 208. The master device 202 may be, but is not limited to, a CPU, GPU, a direct memory access (DMA) controller and the like, that sends memory requests to the memory controller 204. The memory device 206 may include a volatile or non-volatile memory, for example, RAM, DRAM, or a cache. The memory controller 204 can be a separate chip or integrated into another chip, such as on the die of a microprocessor. It is understood that the device 200 may include additional components not shown in FIG. 2.

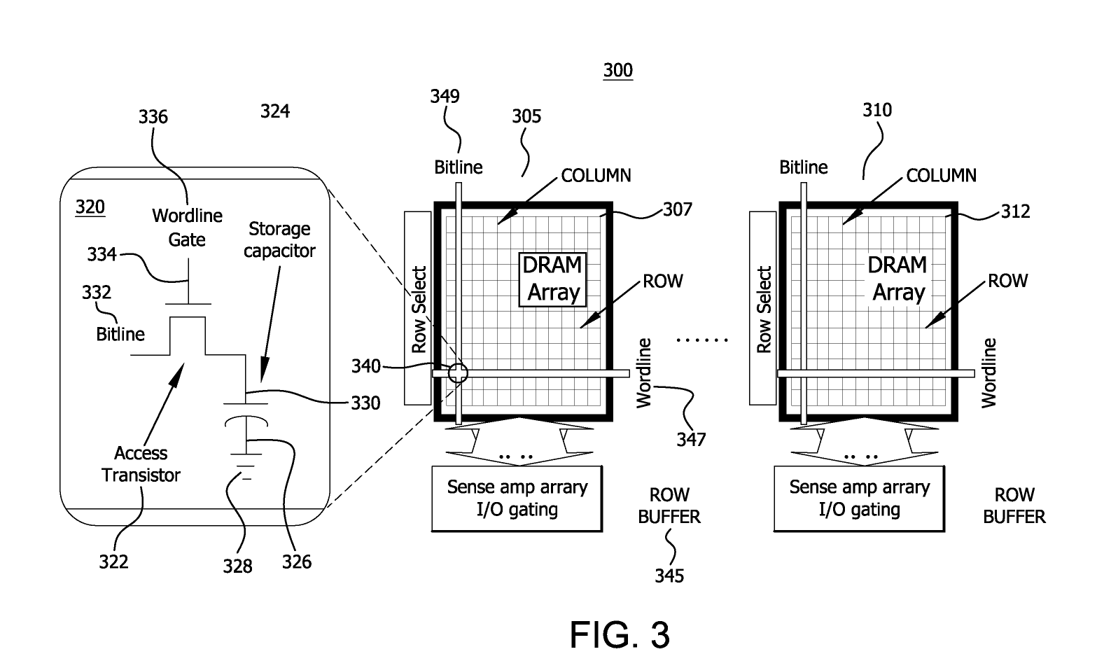

FIG. 3 shows an example memory device 300 in accordance with some embodiments. Memory devices, such as those based on DRAM and phase change memory (PCM) technology consists of several independent banks 305 and 310. Each bank 305 and 310 is arranged as a two-dimensional array of memory cells 307 and 312, respectively. For purposes of illustration, the following description is with respect to a DRAM type memory device. Other technologies for the memory device 300 may be used. For example, for a DRAM type memory device, each memory cell 320 has an access transistor 322 and a storage capacitor 324. One electrode 326 of the storage capacitor 324 is connected to ground 328 and another electrode 330 is connected through the access transistor 322 to a bit line 332. A control terminal 334 of the access transistor 322 is connected to a word line 336.

To access a block of data 340, a row of data is first brought into a series of sense-amplifiers and latches, (internal to the device 300, and one per bank 305 . . . 310), which constitute a row buffer 345. This operation is termed as row activation and is performed by issuing a row activation command (ACT) along with an address for the specific row, (i.e. selecting a word line 347). To access the desired block 340, (which is a subset of the selected row), a column read (RD) or column write (WR) command is then issued along with a column address to respectively read from or write to the open row in the row buffer 345, (i.e. selecting a bit line 349).

In the case of an RD command, the data from the columns selected by the column address is moved from the row buffers 345 to external input/output (I/O) pins (not shown) and subsequently driven over an external memory channel to a memory controller, (for example, over memory channel 208 to memory controller 204 as shown in FIG. 2). In the case of the WR command, the data is first sent from the memory controller 204 to the memory device 300 over the memory channel 208. The data is then moved from the I/O pins into the selected columns of the row buffer 345. The data from the row buffer 345 is then moved into the originally activated row from the row buffer 345.

Intra-bank, inter-row data transfers can be achieved in conventional systems by having a master device issue a sequence of reads from the source row. On the first read, an activate command is issued with the source row address by the memory controller 204, following which the row's data is brought into the memory bank's row buffer 345. A series of RD commands are then issued for each block in the row buffer 345 and the data is returned over the data bus. For example, in a specific configuration of current double data rate type three (DDR3) systems, a single row activation in a 1 GB DRAM dual in-line memory module (DIMM) fetches 16 KB of data in to row buffers. This amounts to a total of 256 64-byte transfers.

The data transferred to the memory controller 204 is returned to the master device and then needs to be buffered somewhere. The master device then issues a sequence of writes to write the buffered data to the target row. On the first write, the memory controller 204 issues a precharge command to the bank, which closes the open row, (i.e. the source row). The target row is then activated using the ACT command. A series of WR commands are then issued to write back each block to the row buffer 345. The target row has all the data stored in it after the write-recovery time has passed since the last block has been transferred over the pins. Such a transfer may be broken up into smaller blocks of data to reduce the buffering in the host at the cost of separate activations of source and target rows for each block.

As illustrated, the memory channel 208 remains occupied for the entire duration and cannot service any other requests from the bank for the entire duration. Since the compute units do not benefit directly from this transfer, this bandwidth use can be viewed as a waste of bandwidth. This can result in significant system slowdown since memory bandwidth is one of the most important system resources. This reduction in available bandwidth and the consequent contention for the banks arises even if other requests can be interleaved among the read or write requests.

Described herein is a method and apparatus for inter-row data transfer in memory devices without engaging the external I/O pins on the memory device. As described herein below, the master device is relieved from reading and writing each data block, (or word), the memory controller is relieved from performing each micro-operation and the participation of the I/O pins is not required as the data is not moved out of the memory chip. The method and apparatus minimize overhead on the master devices orchestrating the transfer and streamlines participation of the memory controller. There is no engagement of the I/O pins and memory data channel. In addition, there is a relatively quick turnaround with respect to the bank, which reduces the bank conflict overhead.

As illustrated herein below, the method and apparatus lowers the absolute latency of the transfer operation since all bits of the transfer are read simultaneously and written simultaneously. This frees up the bank faster. This also frees up the channel bandwidth, which in turn allows data transfer to and from other banks and ranks on the channel while a row transfer (RT) command is executed on a bank as described herein below. Moreover, the extra energy consumption on the I/O pins for the wasteful to-and-fro data transfer is eliminated, extra storage in the master device is eliminated and use of the address and command bus is minimized.

The method and apparatus may be useful in operations that require copying large amounts of data, (i.e. those that span entire memory rows). These operations may include application level operations, (for example, the duplication of large data structures) and system software operations, (for example, copy-on-write duplication of large memory pages).

In an embodiment, a memory controller is augmented to issue a new command, a row transfer (RT). The RT command requires that a bank identifier, a source row identifier and a target row identifier be specified. In some embodiments, issuing this command may occupy the memory interface for 2 cycles in contrast to the 1 cycle needed to issue conventional memory operations.

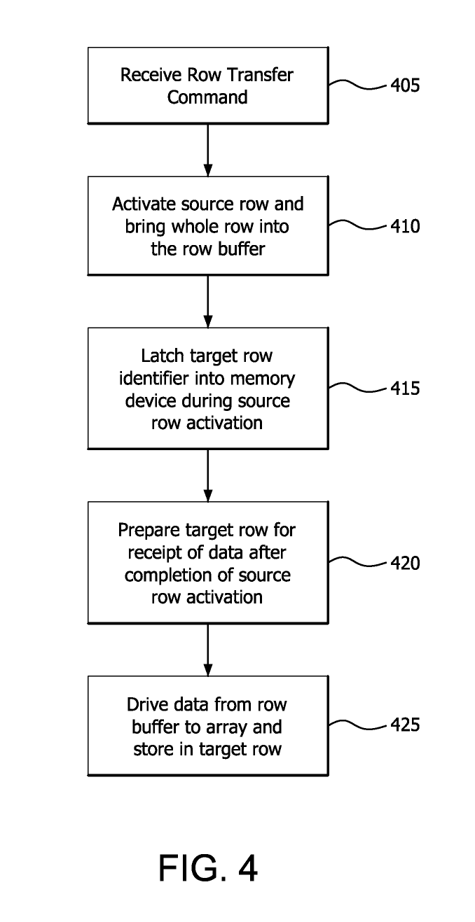

A memory device is correspondingly enhanced to perform a set of operations upon receipt of the RT command (405) as shown in FIG. 4. Initially, a source row is activated and the whole row is brought into the row buffer (410). The target row identifier is latched into the memory device while the source row is being activated (415). After the source row activation is completed, (i.e. the source row data is stored in the row buffer), the target row is prepared to receive the data from the row buffer (420). This entails activating the word line of the target row to prepare for a write operation. The data from the row-buffer is then driven back to the array and stored in the target row (425). This happens in parallel for all bits in the row buffer. After the entire operation is complete, the bank is free to be used for other operations.

In another embodiment, the RT command permits a subset of a row to be duplicated into the corresponding subset of another row, (instead of duplicating the entire row as in the embodiment described hereinabove). In this embodiment, the RT command includes a specification of which columns within the rows are to be duplicated. For example, this can be specified by a (start, length) tuple at a power-of-2 granularity, (which reduces the encoding overhead), or a more generic encoding enabling more flexible regions to be copied at the expense of more command encoding overhead. In another example, a (start, end) tuple can be used.

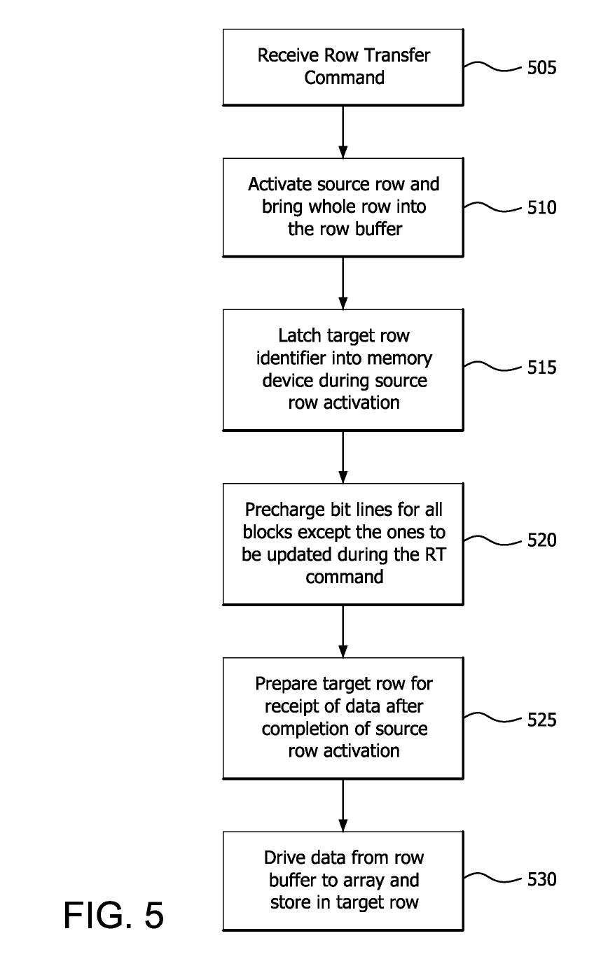

A memory device is correspondingly enhanced to perform a set of operations upon receipt of the RT command (505) as shown in FIG. 5. Initially, a source row is activated and the whole row is brought into the row buffer (510). The target row identifier is latched into the memory device while the source row is being activated (515). After the source row activation is completed, (i.e. the source row data is stored in the row buffer), bit lines are precharged for all blocks except the ones to be updated during the RT command (520). In some embodiments, the memory device is further enhanced to selectively precharge bit lines for some columns. This overhead may be reduced by restricting the selective precharge granularity at a quarter or some such fraction of a row. The target row is prepared to receive the data from the row buffer (525). This entails activating the word line of the target row to prepare for a write operation and results in updating the data in the unmasked columns that were not precharged. The contents of the masked, precharged columns of the target row are read in to the row buffer. The data from the row buffer is then driven back to the array and stored in the target row (530). This happens in parallel for all bits in the row buffer. After the entire operation is complete, the bank is free to be used for other operations.

The above masked inter-row copy operation can be used to accelerate data copies in regions smaller than an entire memory page, (for example, 4 KB OS pages), as long as the copy operation is among aligned regions within the source and destination rows. The alignment may need to be ensured by OS techniques, (on copy-on-write of 4 KB pages, the OS can ensure both the source and destination pages are aligned within the memory row within the same memory bank).

In another embodiment, a memory controller may be augmented with a “PRECHARGE TO ADDRESSED ROW” (PREAR) command. The PREAR command has a bank identifier and row address. In some embodiments, the PREAR command may use the same format as an ACT command and therefore use the same command addressing interface. This embodiment eliminates the need for a state machine in the memory device. For example, in the RT embodiment, the memory device needs to maintain a state machine to track the flow of operations shown in FIG. 4.

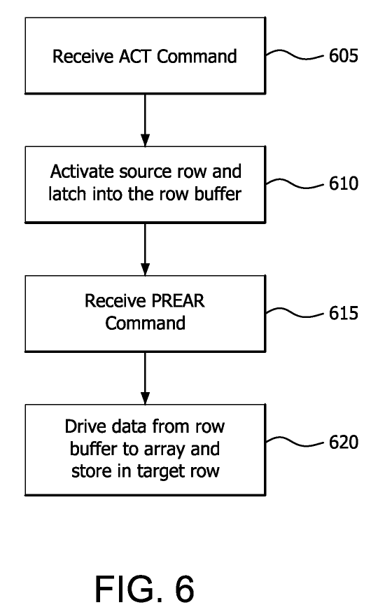

FIG. 6 shows an operational example of the PREAR command. A memory controller receives an ACT command (605) that activates the source row and latches it into the row buffer (610). The memory device receives the PREAR command after receipt of the ACT command (615). The source row is still latched in the row buffer from the earlier ACT command. The data from the row buffer is driven back to the array and stored in a target row (620). This happens in parallel for all bits in the row buffer.

Table 1 shows an example operation to copy a row with the PREAR command. The memory controller issues an ACT command which copies the contents of the source row into the row buffer and destroys the data stored in the source row. The ACT command is followed by issuance of a PREAR command which writes data in the row buffer to the target row. The PREAR command in turn is followed by issuance of a precharge (PRE) command which writes the data in the row buffer back to the source row.

TABLE 1

| | |
|---|---|
| ACT <bank>, <source row> | // Copy contents of source row into row |
| | buffer |
| | // Destroys data stored in source row |

PREAR <bank>, <target row> // Write copy of data to target row
PRE <bank> // Write back data to original source row

Table 2 shows an example operation to move a row with the PREAR command. The memory controller issues an ACT command which copies the contents of the source row into the row buffer and destroys the data stored in the source row. The ACT command is followed by issuance of a PREAR command which writes the data in the row buffer to the target row.

TABLE 2

| | |
|---|---|
| ACT <bank>, <source row> | // Copy contents of source row into row |
| | buffer |
| | // Destroys data stored in source row |

PREAR <bank>, <target row> // Write data to target row

Compared to the RT command embodiment, the PREAR command may require additional command interface bandwidth and increased complexity in the memory controller sequencing, (i.e. a complicated state machine). The benefit is a simpler memory device with less complex internal sequencing and simpler command processing.

In another embodiment, the PREAR command could be replaced by a sequence of commands consisting of a new command latch addressed row (LAR) and then a PRE command. Such an embodiment requires that the PRE command preserves row buffer contents. The LAR command uses a bank identifier and a target row identifier, and latches the row address of the target row to allow the bank's row decoder to address the intended row.

Table 3 shows an example operation to copy a row with the LAR command. The memory controller issues an ACT command which copies the contents of the source row into the row buffer and destroys the data stored in the source row. The ACT command is followed by issuance of a PRE command which writes data back to the source row. The PRE command in turn is followed by issuance of a LAR command which latches the row address of the target row. The LAR command in turn is followed by a PRE command which writes the data in the row buffer to the target row.

TABLE 3

| | |
|---|---|
| ACT <bank>, <source row> | // Copy contents of source row into row |
| | buffer |
| | // Destroys data stored in source row |

PRE <bank> // Write back data to original source row
LAR <bank>, <target row> // latch row address of the target row
PRE <bank> // Write copy of data to target row

Table 4 shows an example operation to move a row with the LAR command. The memory controller issues an ACT command which copies the contents of the source row into the row buffer and destroys the data stored in the source row. The ACT command is followed by issuance of a LAR command which latches the row address of the target row. The LAR command is followed in turn by a PRE command which writes the data in the row buffer to the target row.

TABLE 4

| | |
|---|---|
| ACT <bank>, <source row> | // Copy contents of source row into row |
| | buffer |
| | // Destroys data stored in source row |

LAR <bank>, <target row> // latch row address of the target row
PRE <bank> // Write copy of data to target row

This approach may further increase command bandwidth, (as compared to the PREAR approach), but may simplify the internal circuitry and timing in the memory device.

In general, in accordance with some embodiments, a method for inter-row data transfer in a memory device is responsive to a row transfer (RT) command which includes a source row identifier and a target row identifier. The RT command may also include a bank identifier. The method includes performing the following actions upon receipt of the RT command. A source row is activated and source row data is stored in a row buffer. In some embodiments, a subset of the row buffer is stored in the target row. For example, the RT command may identify certain columns within the row buffer to be stored in the target row. This may be implemented by using start and length fields or start and end fields. The target row identifier is latched into the memory device and a word line of a target row is activated to prepare for a write operation. This may be done during activation of the source row. The source row data from the row buffer is stored into the target row.

In some embodiments, a method for inter-row data transfer in a memory device includes receiving an activation (ACT) command. The method further includes activating a source row and latching the source row data in a row buffer. A precharge to addressed row (PREAR) command is then received which includes a bank identifier and a row address. The source row data from the row buffer is then stored in a target row. A precharge (PRE) command may be received which writes the source row data in the row buffer to the source row.

In some embodiments, a method for inter-row data transfer in a memory device includes receiving an activation (ACT) command. The method further includes activating a source row and latching the source row data in a row buffer. A latch addressed row (LAR) command is then received which includes a bank identifier and a target row identifier. The row address of a target row is latched to allow a row decoder to address the target row. A precharge (PRE) command is then received which writes the source row data in the row buffer to the target row. A precharge (PRE) command may be received which writes the source row data in the row buffer to the source row. In an embodiment, the PRE command is received after the ACT command and before the LAR command.

It should be understood that many variations are possible based on the disclosure herein. Although features and elements are described above in particular combinations, each feature or element may be used alone without the other features and elements or in various combinations with or without other features and elements.

The methods provided may be implemented in a general purpose computer, a processor, or a processor core. Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Such processors may be manufactured by configuring a manufacturing process using the results of processed hardware description language (HDL) instructions and other intermediary data including netlists (such instructions capable of being stored on a computer readable media). The results of such processing may be maskworks that are then used in a semiconductor manufacturing process to manufacture a processor which implements aspects of the embodiments.

The methods or flow charts provided herein, to the extent applicable, may be implemented in a computer program, software, or firmware incorporated in a computer-readable storage medium for execution by a general purpose computer or a processor. Examples of computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A method for inter-row data transfer in a memory device, comprising:
responsive to a row transfer (RT) command including a source row identifier and a target row identifier,
activating a source row corresponding to the source row identifier and storing source row data in a row buffer;
latching the target row identifier into the memory device;
activating a word line of a target row corresponding to the target row identifier to prepare for a write operation; and
storing the source row data from the row buffer into the target row.

2. The method of claim 1, wherein the row transfer (RT) command includes a bank identifier.

3. The method of claim 1, wherein the target row identifier is latched into the memory device during activation of the source row.

4. The method of claim 1, wherein a subset of the row buffer is stored in the target row.

5. The method of claim 1, wherein the RT command identifies certain columns within the row buffer to be stored in the target row.

6. The method of claim 1, wherein the RT command includes a start and length field to identify certain columns within the row buffer to be stored in the target row.

7. The method of claim 1, wherein the RT command includes a start and end field to identify certain columns within the row buffer to be stored in the target row.

8. The method of claim 1, further comprising precharging bit lines for blocks not being updated during the RT command.

9. The method of claim 8, wherein activation of the word line of the target row results in updating the data in unmasked columns that were not precharged.

10. A method for inter-row data transfer in a memory device, comprising:
receiving an activation (ACT) command;
activating a source row and latching the source row data in a row buffer; and
receiving a precharge to addressed row (PREAR) command which includes a bank identifier and a row address, wherein the source row data from the row buffer is stored in a target row.

11. The method of claim 10, further comprising:
receiving a precharge (PRE) command which writes the source row data in the row buffer to the source row.

12. A method for inter-row data transfer in a memory device, comprising:
receiving an activation (ACT) command;
activating a source row and latching the source row data in a row buffer;
receiving a latch addressed row (LAR) command which includes a bank identifier and a target row identifier, wherein the row address of a target row is latched to allow a row decoder to address the target row; and
receiving a precharge (PRE) command which writes the source row data in the row buffer to the target row.

13. The method of claim 12, further comprising:
receiving a precharge (PRE) command which writes the source row data in the row buffer to the source row, wherein the PRE command is received after the ACT command and before the LAR command.

14. A device, comprising:
a memory device configured to respond to a row transfer (RT) command which includes a source row identifier and a target row identifier and configured to:
activate a source row corresponding to the source row identifier and storing source row data in a row buffer;
latch the target row identifier into the memory device;
activate a word line of a target row corresponding to the target row identifier to prepare for a write operation; and
store the source row data from the row buffer into the target row.

15. The device of claim 14, wherein the RT command includes a bank identifier.

16. The device of claim 14, wherein the target row identifier is latched into the memory device during activation of the source row.

17. The device of claim 14, wherein a subset of the row buffer is stored in the target row.

18. The device of claim 14, wherein the RT command identifies certain columns within the row buffer to be stored in the target row.

19. The device of claim 14, wherein the RT command includes a start and length field to identify certain columns within the row buffer to be stored in the target row.

20. The device of claim 14, wherein the RT command includes a start and end field to identify certain columns within the row buffer to be stored in the target row.

21. The device of claim 14, wherein the memory device is configured to precharge bit lines for blocks not being updated during the RT command.

22. The device of claim 21, wherein activation of the word line of the target row results in updating the data in unmasked columns that were not precharged.
